(19) United States
(12) Patent Application Publication
(10) Pub. No.: US 2026/0164772 A1
(43) Pub. Date: Jun. 11, 2026

(54) SEMICONDUCTOR STRUCTURE AND METHODS FOR FORMING THE SAME

(71) Applicant: Vanguard International Semiconductor Corporation, Hsinchu (TW)

(72) Inventors: Tzu-Hsuan CHEN, Hsinchu City (TW); Yu-Jui CHANG, Hsinchu City (TW); Yun-Kai LAI, Taichung City (TW); Chien-Hsien SONG, Kaohsiung City (TW); Chen-Dong TZOU, Taipei City (TW); Chia-Hao LEE, Zhubei City (TW); Chung-Ren LAO, Taichung City (TW); Chih-Cherng LIAO, Zhudong Township (TW)

(73) Assignee: Vanguard International Semiconductor Corporation, Hsinchu (TW)

(21) Appl. No.: 18/970,175

(22) Filed: Dec. 5, 2024

(51) Int. Cl. H10D 84/83; H10D 84/01; H10D 84/85

(52) U.S. Cl. CPC H10D 84/8311; H10D 84/013; H10D 84/0149; H10D 84/016; H10D 84/0186; H10D 84/0188; H10D 84/0191; H10D 84/835; H10D 84/839; H10D 84/85

(57) ABSTRACT

A semiconductor structure includes a substrate having a first conductivity type, an epitaxial layer on the substrate and having the first conductivity type, a first region that extends from the top surface of the epitaxial layer into the epitaxial layer, a first device disposed in the first region, a second region having a second conductivity type and extending from the top surface of the epitaxial layer into the epitaxial layer, and a second device disposed in the second region, wherein the substrate functions as a drain electrode of the first device. The second region is located at one side of the first region. A portion of the epitaxial layer extends between the first region and the second region to separate the first region from the second region.

### BACKGROUND OF THE INVENTION

### Field of the Invention

The present invention relates to a semiconductor structure and a method for forming the same, and in particular it relates to a semiconductor structure integrating multiple different types of components on the same substrate and a method for forming the same.

### Description of the Related Art

The semiconductor industry continues to improve the integration density of different electronic components by continuously reducing the minimum component size, so that more components may be integrated into a given area. Integrating different types of components on the same substrate has also been tried. However, as the electrical performance requirements of semiconductor devices continue to increase, the complexity of integration of semiconductor devices and methods for forming them has also increased.

Taking lateral diffused metal oxide semiconductor (LDMOS) components as an example, these may meet the requirements of high output power and gate-source breakdown voltage greater than 60 volts. They are mainly used in high-end amplifiers and radio power amplifiers for wireless cellular networks. The driving current of the LDMOS device is in the plane direction. Vertical-diffused metal oxide semiconductor (VDMOS) components have the characteristics of high voltage resistance and are widely used in power switch components. The driving current of VDMOS components flows in the vertical direction. Currently, LDMOS components and VDMOS components with different driving current directions are integrated onto the substrate. In addition to the increased complexity of the formation method, the electrical performance of each component in operation may easily be affected by other, different types of components and may not meet the application requirements. Thus, while existing semiconductor devices have, individually, generally been adequate and sufficient for their intended purposes, they are not entirely satisfactory in terms of integrated fabrication.

### BRIEF SUMMARY OF THE INVENTION

Some embodiments of the present disclosure provide a semiconductor structure, including a substrate having a first conductivity type; an epitaxial layer located on the substrate, wherein the epitaxial layer having the first conductivity type. The semiconductor structure further includes: a doping region extending from the top surface of the epitaxial layer into the epitaxial layer, wherein the first doping region has the first conductivity type. The semiconductor structure further includes: a first device located in the first doping region, wherein the substrate functions as a drain electrode of the first device. The semiconductor structure further includes: a second doping region extending from the top surface of the epitaxial layer into the epitaxial layer, wherein the second doping region has a second conductivity type, wherein the second doping region is located at a side of the first doping region, wherein a portion of the epitaxial layer extends between the first doping region and the second doping region to separate the first doping region from the second doping region. The semiconductor structure further includes a second device located in the second doping region.

Some embodiments of the present disclosure also provide a method for forming a semiconductor structure, including: providing a substrate having a first conductivity type; forming an epitaxial layer having the first conductivity type on the substrate; forming a first doping region in the epitaxial layer, wherein the first doping region extends from the top surface of the epitaxial layer in a direction toward the substrate, wherein the first doping region has the first conductivity type. The method further includes: forming a first device in the first doping region, wherein the substrate functions as a drain electrode of the first device. The method further includes: forming a second doping region in the epitaxial layer, wherein the second doping region extends from the top of the epitaxial layer in a direction toward the substrate, wherein the second doping region has a second conductivity type. The second doping region is located on a side of the first doping region, wherein a portion of the epitaxial layer extends between the first doping region and the second doping region to separate the first doping region from the second doping region. The method further includes forming a second device in the second doping region.

### BRIEF DESCRIPTION OF THE DRAWINGS

The present disclosure can be more fully understood by reading the subsequent detailed description and examples with references made to the accompanying drawings, wherein:

FIG. 1 is a cross-sectional view of a semiconductor structure at an intermediate manufacturing stage according to some embodiments of the present disclosure.

FIGS. 2A, 2B, 2C, 2D are cross-sectional views of a semiconductor structure at intermediate manufacturing stages according to the some embodiments of the present disclosure.

FIG. 3 is a cross-sectional view of a semiconductor structure at an intermediate manufacturing stage according to some embodiments of the present disclosure.

FIG. 4 is a cross-sectional view of a semiconductor structure at an intermediate manufacturing stage according to some embodiments of the present disclosure.

FIG. 5 is a cross-sectional view of a semiconductor structure at an intermediate manufacturing stage according to some embodiments of the present disclosure.

### DETAILED DESCRIPTION OF THE INVENTION

The following disclosure provides many embodiments or examples for implementing different elements of the provided semiconductor devices. Specific examples of each component and its configuration are described below to simplify the description of the embodiments of the present invention. Of course, these are only examples and are not intended to limit the embodiments of the present invention. For example, if a description mentions that a first component is formed on a second component, it may include an embodiment in which the first and second components are in direct contact, or may include an additional component formed between the first and second components, so that they are not in direct contact. In addition, embodiments of the present invention may repeat reference numbers and/or letters in different examples. This repetition is for the sake of brevity and clarity and is not intended to indicate the relationship between the various embodiments discussed.

Furthermore, spatially related terms may be used in the following descriptions, such as “under”, “below”, “underneath”, “above”, “over” and other similar terms are used to simplify the description of the relationship between one element or component and other elements or other components as shown in the figures. Such spatially relative terms include, in addition to the directions depicted in the figures, various orientations of the device during use or operation. The device may be otherwise oriented (rotated 90 degrees or at other orientations) and the spatially relative descriptors used herein interpreted accordingly.

Some variations of the embodiments are described below. Similar reference numbers are used to identify similar components in the various figures and illustrated embodiments. It will be appreciated that additional steps may be provided before, during, and after the method, and some of the recited steps may be replaced or deleted for other embodiments of the method.

The present disclosure provides semiconductor structures and methods for forming the same, which include multiple different types of metal-oxide-semiconductor (MOS) devices. In addition, each MOS component may have good electrical performance through the appropriate configuration of isolation areas and/or components according to the conditions of the application components. Furthermore, the method for forming a semiconductor structure proposed in the embodiment has a simple manufacturing process and does not require expensive manufacturing costs, and may integrate different types of MOS devices on the same substrate (such as a wafer).

The content of the embodiments may be applied to integrating multiple MOS devices on a substrate, such as complementary metal oxide semiconductor devices (complementary MOS; CMOS), lateral-diffused metal oxide semiconductor devices (lateral-diffused; LDMOS), double-diffused metal oxide semiconductor field effect transistor (double-diffused MOS; DMOS), vertical-diffused metal oxide semiconductor (vertical-diffused MOS; VDMOS) or other MOS devices. For example, bipolar transistors, CMOS, DMOS and VDMOS transistors may be integrated on the same substrate. However, the present disclosure is not limited to these.

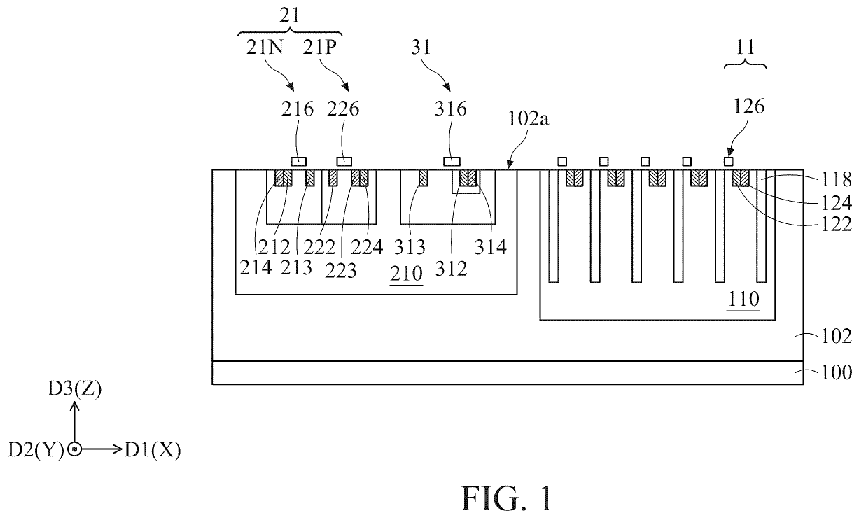

FIG. 1 is a cross-sectional view of a semiconductor structure at an intermediate manufacturing stage according to some embodiments of the present disclosure. This example proposes multiple components of integration, such as the first device 11, the second device 21 and the third device 31, on a substrate 100 to form the semiconductor structure 1. The first device 11 is a vertical metal oxide semiconductor device, such as a VDMOS device. The second device 21 and the third device 31 are non-vertical metal oxide semiconductor devices, such as a CMOS device and an LDMOS device respectively.

In this example, the substrate 100 is, for example, a silicon wafer doped with a dopant with a first conductivity type. The epitaxial layer 102, appropriate well regions, heavily doping regions, gate structures, insulating layers, contacts and other related components are formed on the substrate 100 to form the first device 11, the second device 21 and the third device 31. In an application in which a vertical metal oxide semiconductor device is used as the first device 11, the substrate 100 with the first conductivity type may be used as a drain region of the first device 11. In an example, the first conductivity type is n-type, but the present disclosure is not limited thereto. In some other examples, the first conductivity type may also be a p-type which is the opposite conductivity type to n-type.

Furthermore, in some embodiments, the epitaxial layer 102 has the same conductivity type as the substrate 100. In an example, the epitaxial layer 102 has the first conductivity type, such as (but not limited to) n-type. Moreover, according to some embodiments of the present disclosure, the doping concentration of the substrate 100 is greater than the doping concentration of the epitaxial layer 102.

In this example, the semiconductor structure 1 further includes a first doping region 110 extending from the top surface 102a of the epitaxial layer 102 into the epitaxial layer 102, and the first device 11 is located in the first doping region 110. The first doping region 110 has the same conductivity type as the substrate 100. In an example, the first doping region 110 has a first conductivity type, such as (but not limited to) n-type. Moreover, according to some embodiments of the present disclosure, the doping concentration of the first doping region 110 is greater than the doping concentration of the epitaxial layer 102.

Furthermore, in applications where non-vertical metal oxide semiconductor devices are used as the second device 21 and the third device 31, the second device 21 and the third device 31 are formed in an region with a conductive type different from that of the substrate 100 to reduce the influence of substrate 100 with the first conductive type on the operation of the second device 21 and the third device 31.

In an embodiment, the substrate 100 and the epitaxial layer 102 have a first conductivity type, such as n-type; and the second device 21 and the third device 31 are formed in the second doping region 210 with the second conductivity type, such as a p-type region. The second doping region 210 extends from the top surface 102a of the epitaxial layer 102 in the direction toward the substrate 100. Furthermore, the second doping region 210 and the first doping region 110 are separated by a distance. For example, as shown in FIG. 1, a portion of the epitaxial layer 102 extends between the first doping region 110 and the second doping region 210, so that the first doping region 110 and the second doping region 210 are separated, to further reduce the interference between operating the first device 11 and the second device 21 or/and the third device 31. In an embodiment, the substrate 100 and the epitaxial layer 102 are p-type, the first doping region 110 is p-type, and the second doping region 210 is n-type.

Furthermore, in some embodiments, compared to the second doping region 210, the first doping region 110 may be deeper into the epitaxial layer 102 and closer to the substrate 100. In the example where the first device 11 is a VDMOS device, the closer the first doping region 110 is to the substrate 100 serving as a drain electrode, the electrical performance of the VDMOS device may be improved.

Although, in some embodiments, as shown in FIG. 1, the second device 21 and the third device 31 are formed corresponding to the second doping region 210, the present disclosure is not limited to this. In some other embodiments, the second device 21 and the third device 31 may also be formed at two different regions respectively. For example, the second device 21 is formed in the second doping region 210, and the third device 31 is formed in the third doping region (not shown in FIG. 1), in which the second doping region 210 and the third doping region have the second conductivity type, such as p-type.

Referring again to FIG. 1, in some embodiments, one or more first devices 11 may be disposed in the first doping region 110. In an example in which a VDMOS device is used as the first device 11, the first device 11 includes an adjacent disposed heavily doping portion 122 and a heavily doping portion 124 to respectively serve as a source region of the first device 11 and a bulk region. The heavily doping portion 122 and the first doping region 110 have the same conductivity type, and the heavily doping portion 124 and the heavily doping portion 122 have different conductivity types. In an example, the heavily doping portion 122 and the first doping region 110 have the first conductivity type, such as (but not limited to) n-type; the heavily doping portion 124 has the second conductivity type, such as (but not limited to) p-type.

In some embodiments, the first device 11 includes a planar gate structure. As shown in FIG. 1, the first device 11 includes a gate structure 126 located on the epitaxial layer 102 and spanning the heavily doping portion 122 and a portion of the first doping region 110 (which is the drift region R_{D} of the first device 11). The gate structure 126 includes, for example, a gate dielectric layer (not shown) and a gate electrode located above the gate dielectric layer.

In some embodiments in which the VDMOS device is the first device 11, the first device 11 further includes a trench structure 118. The trench structure 118 includes conductive materials and extends from the top surface 102a of the epitaxial layer 102 in a direction toward the substrate 100 into the first doping region 110.

In addition, in some embodiments in which the CMOS device is the second device 21, the second device 21 includes an NMOS device 21N and a PMOS device 21P that are adjacently disposed. In an example, the NMOS device 21N is disposed in a p-type well region (P well; PW), and includes heavily doping portions 212, 213, and 214. The heavily doping portion 212 and the heavily doping portion 214 are adjacent disposed to each other, and are respectively the source region and the bulk region of the NMOS device 21N. The heavily doping portion 213 is the drain region of the NMOS device 21N. The heavily doping portion 212 and the heavily doping portion 213 have the same conductivity type, such as (but not limited to) n-type. The heavily doping portion 214 and the heavily doping portion 212 have different conductivity types, and the heavily doping portion 214 is, for example (but not limited to), p-type.

Furthermore, in some embodiments, the NMOS device 21N includes a planar gate structure, for example, the gate structure 216 is located on the epitaxial layer 102 and is located between the heavily doping portion 212 (source region) and the heavily doping portion 213 (drain region). The gate structure 216 includes, for example, a gate dielectric layer and a gate electrode located above the gate dielectric layer.

In an example, the PMOS device 21P is disposed in an n-type well region (N well; NW), and includes heavily doping portions 222, 223, and 224. The heavily doping portion 223 and the heavily doping portion 224 are adjacent disposed to each other and are respectively the source region and the bulk region of the PMOS device 21P. The heavily doping portion 222 is the drain region of the PMOS device 21P. The heavily doping portion 222 and the heavily doping portion 223 have the same conductivity type, such as (but not limited to) p-type. The heavily doping portion 224 and the heavily doping portion 222 have different conductivity types, and the heavily doping portion 224 is, for example (but not limited to) n-type.

Furthermore, in some embodiments, the PMOS device 21P includes a planar gate structure, for example, including the gate structure 226 located on the epitaxial layer 102 and located between the heavily doping portion 222 (source region) and the heavily doping portion 223 (drain region). The gate structure 226 includes, for example, a gate dielectric layer and a gate electrode located above the gate dielectric layer.

In addition, in some embodiments where the LDMOS device is the third device 31, the third device 31 also includes a plurality of heavily doping portions and gate structures. Taking LDNMOS as an example, the third device 31 is disposed in an N-type well region (NW) and includes heavily doping portions 312, 313 and 314. The heavily doping portion 312 and the heavily doping portion 314 are disposed adjacent to each other in a p-type well region (PW) and serve as the source region and bulk region of the LDNMOS device respectively. The heavily doping portion 313 is the drain region of the LDNMOS device. The heavily doping portion 312 and the heavily doping portion 313 have the same conductivity type, such as (but not limited to) n-type. The heavily doping portion 314 and the heavily doping portion 312 have different conductivity types, and the heavily doping portion 314 is, for example (but not limited to) p-type.

Furthermore, in some embodiments, the third device 31 (such as an LDNMOS device) also includes a planar gate structure, for example, including the gate structure 316 located on the epitaxial layer 102 and located between the heavily doping portion 312 (source region) and the heavily doping portion 313 (drain region). The gate structure 316 includes, for example, a gate dielectric layer and a gate electrode located above the gate dielectric layer.

According to some embodiments of the present disclosure, when the first device 11, the second device 21 and the third device 31 are integrated on the same substrate 100, similar components of each device may be made in the same process to save production time and cost. For example, heavily doping portions of each device having the same conductivity type may be made in the same process. As mentioned above, the heavily doping portions 122, 212, 213, 222, 223, 312, and 313 having the first conductivity type (n-type) may be made in the same process. The above-mentioned heavily doping portions 124, 214, 224, and 314 having the second conductivity type (p-type) may be made in the same process. The gate structures of each device (such as, gate structures 126, 216, 226, 316) may be made in the same process.

Although the semiconductor structure shown in FIG. 1 is based on the example of integrating CMOS devices, LDMOS devices and VDMOS devices on the substrate 100, the actual application is not limited to the forms of these MOS device. However, the device type to be integrated is chosen according to the application requirements. Furthermore, the following is an example of a method of integrating VDMOS devices and CMOS devices on the substrate according to some embodiments of the present disclosure with reference to the figures. Please note that the following relevant details are for illustrative purposes only and are not intended to limit the present disclosure.

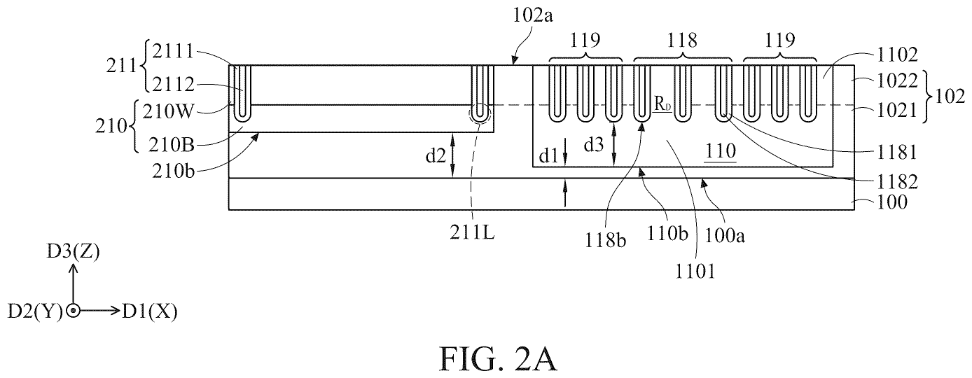

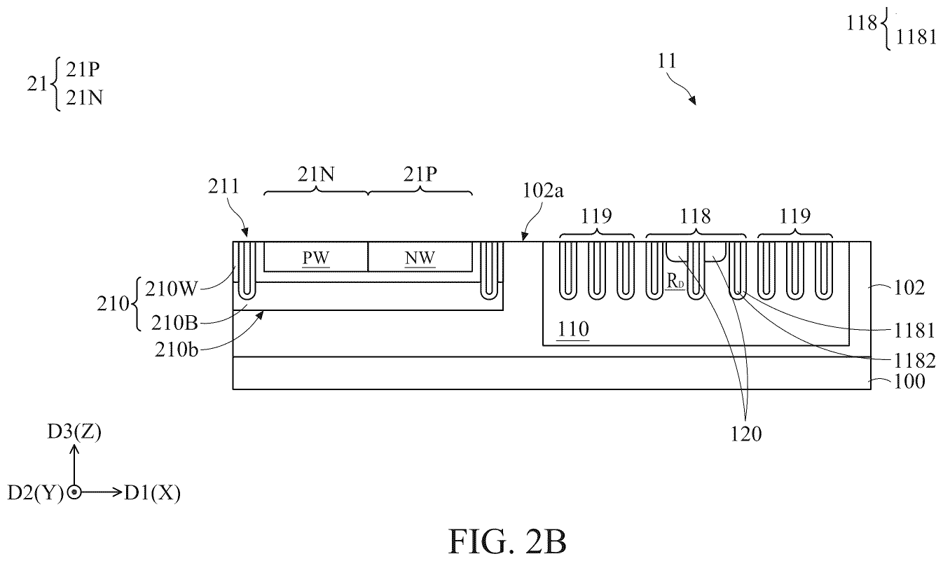

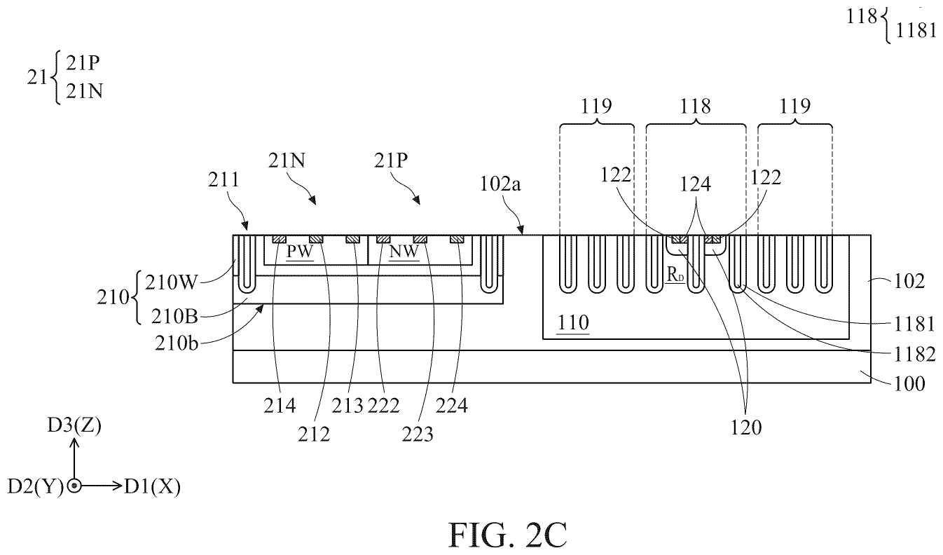

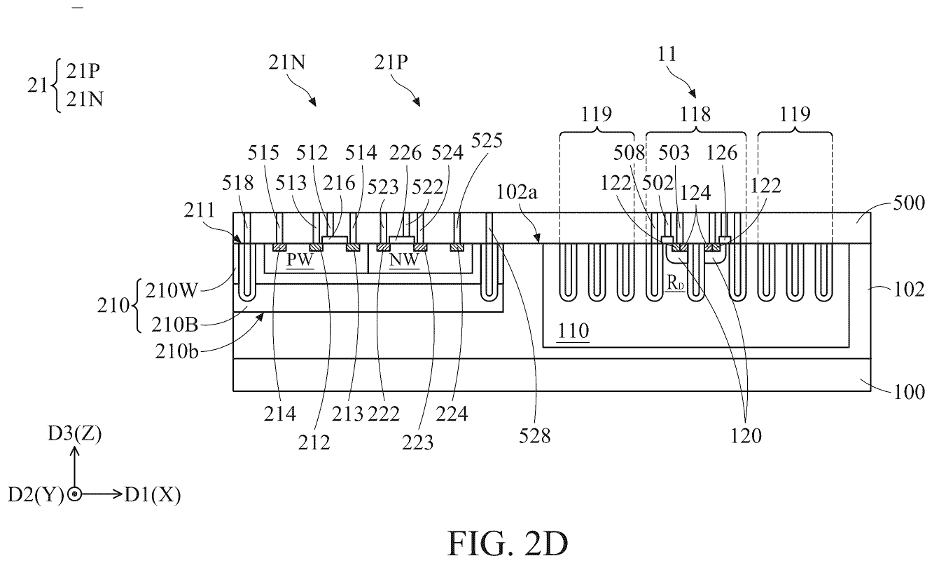

FIGS. 2A to 2D are cross-sectional views of a semiconductor structure in multiple intermediate manufacturing stages according to some embodiments of the present disclosure. Components in FIG. 2A˜2D that are identical or similar to those in FIG. 1 bear the same or similar reference numbers.

Referring to FIG. 2A, according to some embodiments, a substrate 100 having the first conductivity type is provided. In some embodiments, the substrate 100 may be a bulk semiconductor substrate, such as a semiconductor wafer. For example, the substrate 100 is a silicon wafer. In some embodiments, the substrate 100 may be made of silicon or other semiconductor materials, or the substrate 100 may include other elemental semiconductor materials, such as germanium (Ge). In some embodiments, the substrate 100 may include a compound semiconductor, such as silicon carbide, or gallium nitride. In some embodiments, substrate 100 may include an alloy semiconductor such as silicon germanium, silicon germanium carbide, or other suitable substrates. In some embodiments, the substrate 100 may be composed of multiple layers of materials, such as silicon/silicon germanium, silicon/silicon carbide.

In this example, the substrate 100 is, for example, a silicon wafer doped with a dopant of the first conductivity type. Please referring to FIGS. 1 and 2A, in an application where a vertical metal oxide semiconductor device is used as the first device 11, the substrate 100 with the first conductivity type is used as the drain region of the first device 11. In this example, the first conductivity type is n-type. Furthermore, in this example, the substrate 100 extends in the first direction D1 (such as X direction) and the second direction D2 (such as Y direction), and has a thickness in the third direction D3 (such as Z direction).

In some embodiments, an epitaxial growth process is performed to form an epitaxial layer 102 on the substrate 100. During the epitaxial process, for example, the epitaxial layer 102 is formed by growing in the third direction D3 (such as the Z direction). In some embodiments, epitaxial layer 102 has the same conductivity type as substrate 100. In an example, the epitaxial layer 102 has a first conductivity type, such as n-type. Moreover, according to some embodiments of the present disclosure, the doping concentration of the substrate 100 is greater than the doping concentration of the epitaxial layer 102. For example, the doping concentration of the substrate 100 ranges from about 1 E18 atoms/cm³ to about 1 E21 atoms/cm³, and the doping concentration of the epitaxial layer 102 ranges from about 1 E14 atoms/cm³ to about 1 E16 atoms/cm³.

In some embodiments, the interior of the epitaxial layer 102 also includes a plurality of appropriate doping regions, such as the first doping region 110 and the second doping region 210 shown in FIG. 2A. The first doping region 110 and the second doping region 210 are spaced apart from each other in a lateral direction (for example, the first direction D1).

In an example, the first doping region 110 has the first conductivity type, such as (but not limited to) n-type, and the doping concentration of the first doping region 110 is greater than the doping concentration of the epitaxial layer 102. According to some embodiments of the present disclosure, the first doping region 110 is a deep well, such as an n-type deep well (DNW), and extends from the top surface 102a of the epitaxial layer 102 in a direction toward the substrate 100. In some embodiments, the doping concentration of the first doping region 110 ranges from about 1 E16 atoms/cm³ to about 1 E21 atoms/cm³. According to some embodiments, the surface of the first doping region 110 may serve as a channel region for the subsequently formed first device 11.

In this example, the second doping region 210 further includes a buried layer 210B and a well region 210W above the buried layer 210B. Different from the first conductivity type of the substrate 100, the buried layer 210B and the well region 210W have the second conductivity type, such as (but not limited to) p-type. The well region 210W extends from top surface 102 of epitaxial layer 102 into the buried layer 210B. Subsequently, the second device 21 is formed in the well region 210W. That is, there is a buried layer 210B below the second device 21 to further separate it from the substrate 100. Furthermore, the buried layer 210B and the well region 210W have different doping concentrations. In this example, the doping concentration of the well region 210W is greater than the doping concentration of the buried layer 210B.

Furthermore, the epitaxial layer 102 may be formed through a multi-stage epitaxial growth method to form the first doping region 110 and the second doping region 210 inside the epitaxial layer 102.

Referring to FIG. 2A, in some embodiments, an epitaxial growth process may be performed on the top surface 100a of the substrate 100 to form the first epitaxial portion 1021 of the epitaxial layer 102. Afterwards, implantation is performed in the first epitaxial portion 1021 to form the first deep well portion 1101 and the buried layer 210B.

For example, in an example, a patterned mask (not shown) corresponding to the ion implantation region of the first deep well portion 1101 may be provided above the first epitaxial portion 1021, and the ion implantation region of the first deep well portion 1101 is implanted with ions of the first conductivity type (such as n-type) through this patterned mask to form the first deep well portion 1101. The formation of the first deep well portion 1101 in an appropriate depth of the epitaxial layer 102 may be controlled by adjusting the implantation energy or other suitable methods. In some embodiments, the first deep well portion 1101 has a uniform ion doping concentration. In some other embodiments, the first deep well portion 1101 has a gradually varying ion doping concentration.

For example, in an example, a patterned mask (not shown) corresponding to the buried layer 210B may be provided above the first epitaxial portion 1021, and the patterned mask of the buried layer 210B may be implanted with ions (such as boron) of the second conductivity type (such as p-type) through the patterned mask. After that, a high-temperature process, such as a high-temperature furnace tube process, is performed to diffuse the implanted ions to form the buried layer 210B. The formation of the buried layer 210B in an appropriate depth of the epitaxial layer 102 may be controlled by adjusting the implantation energy or other suitable methods. In some embodiments, the buried layer 210B has a uniform ion doping concentration. In some other embodiments, the buried layer 210B has a gradually varying ion doping concentration.

Furthermore, in some embodiments, the doping concentration of the first deep well portion 1101 ranges from about 1 E18 atoms/cm³ to about 1 E21 atoms/cm³. According to some embodiments, the doping concentration of the buried layer 210B ranges from about 1 E15 atoms/cm³ to about 1 E18 atoms/cm³.

After that, referring to FIG. 2A, according to some embodiments, epitaxial growth continues on the top surface of the first epitaxial portion 1021 toward the third direction D3 (for example, the Z direction) to form the second epitaxial portion 1022. The second epitaxial portion 1022 also has the first conductivity type, such as n-type. In this example, the first epitaxial portion 1021 and the second epitaxial portion 1022 together form an epitaxial layer 102.

In some embodiments, metal organic chemical vapor deposition (MOCVD), molecular beam epitaxy (MBE), and hydride vapor phase epitaxy (HVPE), liquid phase epitaxy (LPE), chloride vapor phase epitaxy (Cl-VPE), other suitable process methods or a combination of the aforementioned methods may be used to perform the above-mentioned epitaxial growth process. The epitaxial layer 102 including the first epitaxial portion 1021 and the second epitaxial portion 1022 may be formed by the above-mentioned epitaxial growth process. In applications where a vertical metal oxide semiconductor device is used as the first device 11 to be subsequently formed, the second epitaxial portion 1022 may be used as a drift region of the first device 11.

The doping concentration of the second epitaxial portion 1022 may be less than or substantially equal to the doping concentration of the first epitaxial portion 1021. In some embodiments, the doping concentration of the first epitaxial portion 1021 ranges from about 1 E15 atoms/cm³ to about 1 E16 atoms/cm³. In some embodiments, the doping concentration of the second epitaxial portion 1022 ranges from about 1 E14 atoms/cm³ to about 1 E16 atoms/cm³.

After forming the second epitaxial portion 1022, an ion implantation process is performed to form the second deep well portion 1102 and the well region 210W in the second epitaxial portion 1022, respectively. The second deep well portion 1102 is located on the first deep well portion 1101 and continues the first deep well portion 1101. The second deep well portion 1102 has the first conductivity type, such as n-type. The well region 210W is located on the buried layer 210B and continues from the buried layer 210B. The well region 210W has the second conductivity type, such as p-type. For the formation method of the second deep well portion 1102 and the well region 210W, reference may be made to the above-mentioned related descriptions of the first deep well portion 1101 and the buried layer 210B, which will not be repeated here.

As shown in FIG. 2A, the first deep well portion 1101 and the second deep well portion 1102 form a deep well region to function as the first doping region 110 of the first device 11 formed subsequently. The well region 210W and the buried layer 210B constitute the second doping region 210 of the first device 11 formed subsequently. According to some embodiments, the horizontal position of the buried layer 210B corresponds to the position between the bottom surface 110b of the first doping region 110 and the well region 210W.

The doping concentration of the second deep well portion 1102 may be greater than or substantially equal to the doping concentration of the first deep well portion 1101. In some embodiments, the doping concentration of the second deep well portion 1102 ranges from about 1 E15 atoms/cm³ to about 1 E18 atoms/cm³.

According to some embodiments of the present disclosure, the doping concentration of the epitaxial layer 102 is less than the doping concentration of the substrate 100. For example, in an example, the average doping concentration of the first epitaxial portion 1021 and the second epitaxial portion 1022 is smaller than the doping concentration of the substrate 100.

Furthermore, according to some embodiments of the present disclosure, the doping concentration of the first doping region 110 is greater than the doping concentration of the epitaxial layer 102. For example, in an example, the average doping concentration of the first deep well portion 1101 and the second deep well portion 1102 is greater than the average doping concentration of the first epitaxial portion 1021 and the second epitaxial portion 1022. The first doping region 110 with a high doping concentration may reduce the on-resistance of the subsequently formed first device 11 (such as a VDMOS device), thereby improving the electrical performance of the formed first device 11.

Furthermore, according to some embodiments of the present disclosure, the doping concentration of the well region 210W of the second doping region 210 is greater than the doping concentration of the epitaxial layer 102 and less than the doping concentration of the substrate 100. According to some embodiments, the buried layer 210B of the second doping region 210 is less than the doping concentration of the epitaxial layer 102 and less than the doping concentration of the substrate 100.

Furthermore, according to some embodiments of the present disclosure, the first doping region 110 is closer to the substrate 100 than the second doping region 210. As shown in FIG. 2A, there is a first distance d1 along the third direction D3 between the bottom surface 110b of the first doping region 110 and the top surface 100a of the substrate 100. There is a second distance d2 along the third direction D3 between the bottom surface 210b of the second doping region 210 (that is, the bottom surface 210b of the embedded layer 210B) and the top surface 100a of the substrate 100. The second distance d2 is greater than the first distance d1.

In some embodiments in which a VDMOS device is used as the first device 11, the bottom surface 110b of the first doping region 110 is closer to the substrate 100 with the dopant having the first conductivity type (for example, n-type) as the drain electrode, which may further improve the electrical performance of VDMOS devices. Furthermore, in some embodiments where a CMOS or LDMOS device is used as the second device or third device, in addition to the second doping region 210, the components disposed therein may be well electrically isolated from other components. The farther the bottom surface 210b of the second doping region 210 is from the substrate 100, the influence caused by the substrate 100 having the first conductivity type (such as n-type) to the second device or third device at the second doping region 210 may also be reduced.

According to some embodiments of the present disclosure, in applications where a VDMOS device is used as the first device 11 formed subsequently, a trench structure 118 may also be formed in the first doping region 110. The trench structure 118 extends from the top surface 102a of the epitaxial layer 102 in a direction toward the substrate 100 into the first doping region 110. The bottom of the trench structure 118 does not extend beyond the first doping region 110. That is, the sidewalls and the bottom of each trench structure 118 are surrounded and covered by the first doping region 110.

In some examples in which the bottom surface 110b of the first doping region 110 is close to the substrate 100, the vertical distance (such as the first distance d1) between the bottom surface 110b of the first doping region 110 and the top surface 100a of the substrate 100) may be less than the vertical distance (such as the third distance d3) between the bottom surface 118b of the trench structure 118 and the bottom surface 110b of the first doping region 110.

Furthermore, in some embodiments in which the bottom surface 210b of the second doping region 210 is far away from the substrate 100, the bottommost portion of the trench structure 118 may be at approximately the same level as the bottom surface 210b of the second doping region 210. Alternatively, in some embodiments, the trench structure 118 may extend downwardly to its bottommost portion below the bottom surface 210b of the second doping region 210. That is, the trench structure 118 is closer to the substrate 100 than the second doping region 210. The depth of the trench structure 118 may adjust the vertical current of the VDMOS.

According to some embodiments, each trench structure 118 includes an insulating layer 1181 and a conductive portion 1182. The insulating layer 1181 covers the sidewalls and bottom of the conductive portion 1182. In some embodiments, when viewed from above the substrate 100, the first doping region 110 and the second doping region 210 are separated in the first direction D1 (for example, the X direction). The trench structures 118 in the first doping region 110 extend along the second direction D2 (for example, the Y direction). The trench structures 118 are spaced apart from each other by a distance in the first direction D1 (for example, the X direction). The second direction D2 is different from the first direction D1. For example, the second direction D2 and the first direction D1 are perpendicular to each other.

The mutual configuration of the trench structure 118 proposed in the embodiment and other components formed subsequently may improve the electrical performance of the formed first device. For example, if the conductive portion 1182 of the trench structure 118 is subsequently electrically connected to the gate electrode, the on-resistance may be greatly reduced; or if the conductive portion 1182 of the trench structure 118 is subsequently electrically connected to the source electrode, the on-resistance may be effectively reduced while also having good dynamic characteristics. For example, it may shorten the switching time of turning on and off, and greatly reduce switching energy loss. In an embodiment, the conductive portion 1182 in the trench structure 118 may be a field plate.

According to some embodiments of the present disclosure, the position of the trench structure 118 may be defined through a suitable photolithography patterning process. In some examples, a mask (not shown) is formed over the epitaxial layer 102 and has a plurality of openings to expose the top surface 102a of the first doping region 110. In some embodiments, the mask is a patterned photoresist formed of photoresist material. In some other embodiments, the material of the masks may be a hard mask (HM) composed of an oxide layer and a nitride layer. In some examples where patterned photoresist is used as a mask, the above-mentioned photolithographic patterning process includes photoresist coating (for example, spin coating), soft baking, mask alignment, exposure, post-exposure baking, photoresist development, cleaning and drying (for example, hard baking), other suitable processes, or a combination of the foregoing processes to form these openings.

Afterwards, a portion of the first doping region 110 may be removed through the opening of the mask, for example, one or more etching processes may be performed to form recesses (not shown) in the first doping region 110. In some embodiments, the locations of these recesses correspond to the locations of trench structures 118 as shown in FIG. 2A. The depth of these recesses in the first doping region 110 (for example, along the third direction D3) is equal to the depth of the subsequently formed trench structure 118 in the first doping region 110 (for example, along the third direction D3).

Furthermore, in some embodiments, the etching process includes a dry etching process, a wet etching process, a plasma etching process, a reactive ion etching process, other suitable processes, or a combination of the foregoing processes. In addition, it can be understood that the size, shape and position of the recess and the trench structure 118 formed therein are only for illustrative purposes and are not intended to limit the embodiments of the present invention.

According to some embodiments, after the recess is formed, the mask may be removed through an ashing process, a wet etching process (such as acid etching), or other acceptable processes. After removing the mask, a cleaning process may be optionally performed to remove residues.

In some embodiments, after forming the recesses, an insulating material (not shown) may be conformably deposited on the top surface 102a of the epitaxial layer 102, and the insulating material is deposited on the sidewalls and bottom surface of the recess as a liner layer. The trench structure 118 proposed in the embodiment may be electrically coupled to the source electrode or the gate electrode, so the above-mentioned insulating material may be appropriately selected according to the coupling situation of the trench structure 118 in actual applications.

In some embodiments where the trench structure 118 is electrically coupled to the source electrode, the insulating material may be silicon oxide, germanium oxide, other suitable semiconductor oxide materials, or a combination of the foregoing materials. In some examples, an insulating material may be isotropically formed on the sidewalls and bottom surfaces of the recesses and on the top surface 102a of the epitaxial layer 102 through an oxidation process. In some embodiments, the oxidation process may be thermal oxidation, radical oxidation, or other suitable processes. In some embodiments, a thermal process may also be selectively performed on the insulating material to increase the density of the insulating material. In some embodiments, the aforementioned thermal process may be a rapid thermal annealing (RTA) process.

In some embodiments where the trench structure 118 is electrically coupled to the gate electrode, that is, the trench structure 118 serves as a trench gate structure, the insulating material may be silicon oxide, hafnium oxide, zirconium oxide, aluminum oxide, aluminum hafnium dioxide alloy, silicon hafnium dioxide, silicon hafnium oxynitride, tantalum hafnium oxide, titanium hafnium oxide, zirconium hafnium oxide, other suitable high dielectric constant (high-k) dielectric materials, or combinations of the aforementioned materials. In some embodiments, an insulating material may be formed on the sidewalls and bottom surfaces of the recesses and on the top surface 102a of the epitaxial layer 102 through a deposition process. The deposition process may be, for example, an isotropic deposition process, and may be a physical vapor deposition (PVD) process, a chemical vapor deposition (CVD) process, an atomic layer deposition (ALD) process, other suitable deposition processes, or the combination of th3 foregoing processes.

Then, according to some embodiments, a conductive material (not shown) may be deposited on top of the insulating material through a deposition process, and the conductive material fills the space outside the insulating material in the recess. A thermal process may be selectively performed on the conductive material, such as an annealing process. In some embodiments, the conductive material may be a single-layer or multi-layer structure, and may be formed of amorphous silicon, polycrystalline silicon, or a combination of the foregoing materials. The above deposition process may be a physical vapor deposition (PVD) process, a chemical vapor deposition (CVD) process, other suitable deposition processes, or a combination of the foregoing processes. In some examples, the conductive material includes polycrystalline silicon.

Next, excess insulating material and excess conductive material are removed. For example, the portion of the insulating material and the portion of the conductive material that exceeds the top surface 102a of the epitaxial layer 102 are removed to form a trench structure 118 as shown in FIG. 2A.

In some examples, the step of removing portion of the insulating material and portion of the conductive material may (but is not limited to) include: using a planarization process to remove excess portions of the conductive material and excess portions of the insulating material located above the top surface 102a of the epitaxial layer 102 to expose the top surface 102a of the epitaxial layer 102. The above-mentioned planarization process is, for example, a chemical mechanical polishing (CMP) process, a mechanical polishing process, an etching process, other suitable processes, or a combination of the foregoing processes.

After the above removal step, the remaining portion of the insulating material becomes the insulating layer 1181, and the remaining portion of the conductive material becomes the conductive portion 1182. The conductive portion 1182 and the material layer of the first doping region 110 is separated by insulating layer 1181. In some examples, after the planarization process, the conductive portion 1182 is located on the insulating layer 1181, and the top surface of the conductive portion 1182 and the top surface of the insulating layer 1181 are substantially coplanar with the top surface 102a of the epitaxial layer 102.

In some embodiments, the conductive portion 1182 may selectively include a dopant with the first conductivity type. In this example, the first conductivity type is n-type. In some embodiments, the dopant of conductive portion 1182 may be phosphorus or other suitable dopants. According to some embodiments, if the trench structure 118 is subsequently electrically connected to the gate electrode, the conductive portion 1182 of the trench structure 118 may not only reduce the on-resistance, but the conductive portion 1182 with the first conductivity type may also further enhance the effect of reduced surface electric field (reduced surface filed; RESURF).

In addition, in some embodiments, one or more termination rings 119 may also be formed in the first doping region 110, and the one or more termination rings 119 are located outside the subsequently formed first device 11 and surrounds the first device 11. The termination ring 119 may be used to adjust the electric field distribution at the edge when the first device 11 is operating. It is worth noting that although in the cross-sectional view of FIG. 2A, the termination ring 119 and the trench structure 118 have similar long strip cross-sections, if viewed from above the substrate 100 (not shown), the termination ring 119 is, for example, closely surrounding the periphery of the subsequently formed first device 11.

Furthermore, according to some embodiments, a trench isolation 211 may be formed in the second doping region 210. The trench isolation 211 extends from the top surface of the second doping region 210 of the epitaxial layer 102 in a direction toward the substrate 100. For example, the trench isolation 211extends along the third direction D3. In some examples, the bottom of trench isolation 211 does not extend beyond the bottom of second doping region 210. Furthermore, the bottom of the trench isolation 211 in the second doping region 210 and the bottom of the trench structure 118 in the first doping region 110 may be on approximately the same horizontal plane, or may be on different horizontal planes. There are no restrictions on this, and appropriate design and adjustments may be made according to the actual manufacturing process.

According to some embodiments, although the cross-sectional view of FIG. 2A shows trench isolation members 211 with two long strip section view formed in the second doping region 210, if viewed from above the substrate 100 (not shown), the trench isolation 211 is, for example, closely surrounding the periphery of the subsequently formed second device 21.

Furthermore, the trench isolation 211 may extend through the well region 210W to the buried layer 210B. According to some embodiments, a portion of trench isolation 211 extends into the buried layer 210B. Therefore, the lower portion 211L of the trench isolation 211 is located in the buried layer 210B. In other words, the bottommost surface of the trench isolation 211 is lower than the bottom surface of the well region 210W, as shown in FIG. 2A.

According to the trench isolation 211 proposed in some embodiments, it may form an isolation structure with the buried layer 210B, so that the second device 21 subsequently formed in the second doping region 210 may achieve good electrical isolation from components (such as the first device 11) formed outside the second doping region 210. Especially in some examples where a VDMOS device is used as the first device 11, the substrate 100 functioned as the drain electrode of the first device 11 is connected to a drain operating voltage, which may easily cause electrical instability of other integrated components on the substrate 100 (such as the second device 21 in the second doped region). Through the buried layer 210B, or the isolation structure formed by the buried layer 210B and the trench isolation 211, the second device 21 in the second doping region 210 and the first device 11 in the first doping region 110 may achieve good electrical isolation.

Furthermore, in some embodiments, the doping concentration of the dopant of the second conductivity type of the buried layer 210B may be adjusted, thereby improving the isolation effect between the buried layer 210B and the epitaxial layer 102 (for example, the first epitaxial portion 1021). In some examples, the buried layer 210B and the substrate 100 have opposite conductivity types, and the doping concentration of the second conductive type dopant of the buried layer 210B is less than the doping concentration of the second conductive type dopant of the well region 210W, and is less than the doping concentration of the first conductive type dopant of the substrate 100.

In some embodiments, the trench isolation 211 includes an insulating layer 2111 and a conductive portion 2112. The insulating layer 2111 covers the sidewalls and bottom of the conductive portion 2112. In some embodiments, the insulating layer 2111 includes silicon oxide, germanium oxide, hafnium oxide, zirconium oxide, aluminum oxide, aluminum hafnium dioxide alloy, silicon hafnium dioxide, silicon hafnium oxynitride, tantalum hafnium oxide, titanium hafnium oxide, zirconium hafnium oxide, other suitable materials, or combinations of the foregoing materials. In some embodiments, the conductive portion 2112 includes amorphous silicon, polycrystalline silicon, other suitable materials, or a combination of the foregoing materials. In some examples, the conductive portion 2112 includes polycrystalline silicon.

Furthermore, regarding the formation of the trench isolation 211, reference may be made to the manufacturing method of the trench structure 118 mentioned above or other suitable methods, which will not be repeated here.

According to some embodiments, the trench structure 118 in the first doping region 110 and the trench isolation 211 in the second doping region 210 may have similar configurations and may be produced in the same process to simplify the process, thereby reducing manufacturing costs. For example, the insulating layer 1181 of the trench structure 118 and the insulating layer 2111 of the trench isolation 211 include the same material and are produced in the same process. The conductive portion 1182 of the trench structure 118 and the conductive portion 2112 of the trench isolator 211 include the same material and made in the same process. In some examples, such trench structures 118 and trench isolations 211 may have substantially the same profile, such as the same width and depth.

After forming the trench structure 118 (or the trench structure 118 and the trench isolation 211), referring to FIG. 2B, well regions required for subsequent fabrication of components are formed in the first doped region 110 and the second doped region 210. According to some embodiments, the first device 11 is formed in the first doping region 110, such as a VDMOS device; and the second device 21 is formed in the second doping region 210, such as a CMOS element.

As shown in FIG. 2B, in some embodiments where a VDMOS device is used as the first device 11, a body region 120 is formed in the first doping region 110. The body region 120 has a conductivity type different from that of the first doping region 110, such as the second conductivity type. In this example, the body region 120 is, for example, p-type, which may also be called a p-body region. Furthermore, in some embodiments, one side of the formed body region 120 is in contact with the trench structure 118, and the other side and bottom of the body region 120 are covered by the doping portion of the first doping region 110. According to some embodiments, the body region 120 may be used as a channel region of a VDMOS device.

In subsequent processes, the source region (such as the heavily doping portion 122) and the bulk region (such as the heavily doping portion 124) of the first device 11 may be formed in the body region 120. In some embodiments, the doping concentration of the body region 120 is less than the doping concentration of the source region and the bulk region. In some embodiments, the doping concentration of the body region 120 is, for example, but not limited to, in the range of about 1 E16 atoms/cm³ to about 1 E18 atoms/cm³.

According to some embodiments, the epitaxial layer 102 may be doped from the its top surface 102a through a deposition process, a lithography patterning process, an etching process, and an implantation process to form the body region 120 as shown in FIG. 2B in the first doped region 110. Therefore, the body region 120 is doped downward from the top surface 102a of the doping epitaxial layer 102 in the first doping region 110 to a specific depth.

In an example, an oxide hard mask material layer (not shown) may be deposited over the doping epitaxial layer 102 in the first doping region 110. Then, a patterned photoresist (patterned PR) corresponding to the position of the body region 120 is formed on the oxide hard mask material layer. The oxide hard mask material layer is etched according to the patterned photoresist to form a oxide hard mask. The patterned photoresist is then removed, and the first doping region 110 is doping according to the formed oxide hard mask to form a body region 120 in the first doping region 110. Then, the oxide hard mask is removed.

In addition, in some embodiments where a CMOS device is used as the second device 21, the subsequently formed CMOS device includes an adjacently disposed NMOS device 21N and a PMOS device 21P disposed adjacently. A p-type well region PW and an N-type well region NW are formed in the well region 210W of the second doping region 210. The p-type well region PW is adjacent to the n-type well region NW. The subsequently formed NMOS device 21N corresponds to the p-type well region PW. The PMOS device 21P corresponds to the n-type well region NW. In this example, the p-type well region PW and the n-type well region NW are spaced apart from the trench isolation 211 in a lateral direction (for example, in the first direction D1) by an appropriate space. For details of the manufacturing method of the p-type well region PW and the n-type well region NW, please referring to the above-mentioned description of the manufacturing of the body region 120 and will not be repeated here.

Furthermore, in some embodiments, the p-type well region PW in the second doping region 210 may be formed in the same process as the body region 120 of the same conductivity type in the first doping region 110 to simplify process. For example, a patterned mask (such as an oxide hard mask) is provided above the epitaxial layer 102. According to the patterned mask, the second conductive type dopant is implanted at the positions of the p-type well region PW and the body region 120 to form the p-type well region PW and the body region 120. Then, the patterned mask is removed.

After that, referring to FIG. 2C, the heavily doping portions of each component to be integrated are formed. For example, in some embodiments where a VDMOS device is used as the first device 11, adjacent heavily doping portions 122 and 124 are formed in the body region 120 of the first doping region 110 to respectively function as the source region and the bulk region of the first device 11. The heavily doping portion 124 and the heavily doping portion 122 have different conductivity types. In this example, the heavily doping portion 122 and the first doping region 110 have the same first conductivity type, such as n-type. The heavily doping portion 124 has the second conductivity type, such as p-type.

According to some embodiments, for example, the epitaxial layer 102 is doping from the top surface 102a in the body region 120 of the first doping region 110 to form a heavily doping portion 122 and a heavily doping portion 124 in the body region 120. For example, the epitaxial layer 102 may be doping from the top surface 102a through a deposition process, a photolithographic patterning process, an etching process, and an implantation process to form the heavily doping portion 122 and the heavily doping portion 124. In some embodiments, the doping concentration of the heavily doping portion 122 and the heavily doping portion 124 respectively ranges from about 1 E18 atoms/cm³ to about 1 E21 atoms/cm³.

In some embodiments, the formation of the heavily doping portion 124 may enable the contact 503 (FIG. 2D) subsequently formed above the heavily doping portion 122 to have good ohmic contact with the body region 120. In this example, one side of the heavily doping portion 124 is in contact with the adjacent trench structure 118, for example, the heavily doping portion 124 directly contacts the insulating layer 1181 of the trench structure 118.

In some embodiments where a CMOS device (including an NMOS device 21N and a PMOS device 21P) is used as the second device 21, heavily doping portions 212, 213 and 214 may be formed in the p-type well region PW, and the heavily doping portions 212, 213 and 214 may be spaced apart from each other by appropriate distances. The heavily doping portion 212 and the heavily doping portion 213 may be respectively the source region and the drain region of the subsequently formed NMOS device 21N. The heavily doping portion 214 is the bulk region of the NMOS device 21N. Furthermore, in this example, the heavily doping portion 212 and the heavily doping portion 213 have the same conductivity type, such as (but not limited to) n-type. The heavily doping portion 214 and the heavily doping portion 212 have different conductivity types, and the heavily doping portion 214 is, for example (but not limited to) p-type.

Furthermore, in some embodiments where a CMOS element is used as the second device 21, heavily doping portions 222, 223 and 224 may be formed in the n-type well region NW, and the heavily doping portions 222, 223 and 224 may be spaced apart from each other by appropriate distances. The heavily doping portion 222 and the heavily doping portion 223 may be respectively the drain region and the source region of the subsequently formed PMOS device 21P. The heavily doping portion 224 is the bulk region of the PMOS device 21P. Furthermore, in this example, the heavily doping portion 222 and the heavily doping portion 223 have the same conductivity type, such as (but not limited to) p-type. The heavily doping portion 224 and the heavily doping portion 222 have different conductivity types, and the heavily doping portion 224 is, for example (but not limited to) n-type.

Furthermore, in some embodiments, the heavily doping portions with the same conductivity type in the second doping region 210 and the first doping region 110 may be formed in the same process to simplify the process. For example, the heavily doping portions 122, 212, 213, and 224, which also have the first conductivity type (such as n-type), may be formed by providing a patterned mask (such as an oxide hard mask) over the epitaxial layer 102 and implanting dopants of the first conductivity type at the positions of the heavily doping portions according to the patterned mask; and then the patterned mask is removed. Similarly, the heavily doping portions 124, 214, 222, and 223 that also have a second conductivity type (such as n-type) can be implanted with the second conductivity type at the positions of these heavily doping portions through another patterned mask. Formed by doping; the patterned mask is then removed.

After that, referring to FIG. 2D, the gate structures and contacts of each device are formed above the epitaxial layer 102. According to some embodiments, the first device 11 and the second device 21 include planar gate structures and have similar structures and configurations to facilitate manufacturing together in the same process.

In some embodiments, a gate structure 126 is formed corresponding to the first doping region 110. The gate structure 126 includes, for example, a gate dielectric layer (not shown) and a gate electrode located above the gate dielectric layer. The gate structure 126 is located on the surface of the epitaxial layer 102. Furthermore, the gate structure 126 is adjacent to the heavily doping portion 122 (which is the source region of the first device 11), for example, it spans the heavily doping portion 122 and portion of the first doping region 110 (which is the drift region R_{D} of the source region). In this example, a trench structure 118, which may be a source electrode or a field plate, a body region 120, a heavily doping portion 122, a heavily doping portion 124 and a gate structure 126 may form a VDMOS device, and the substrate 100 is the drain region. Several VDMOS devices may be formed in the first doping region 110.

In some embodiments, a gate structure 216 is formed on the p-type well region PW corresponding to the second doping region 210 to serve as the gate structure of the NMOS device 21N. The gate structure 216 is located on the epitaxial layer 102 and is located between the heavily doping portion 212 (source region) and the heavily doping portion 213 (drain region). The gate structure 216 includes, for example, a gate dielectric layer (not shown) and a gate electrode located above the gate dielectric layer.

Furthermore, in some embodiments, a gate structure 226 is formed on the n-type well region NW corresponding to the second doping region 210 to serve as the gate structure of the PMOS device 21P. The gate structure 226 is located on the epitaxial layer 102 and is located between the heavily doping portion 222 (drain region) and the heavily doping portion 223 (source region). The gate structure 226 includes, for example, a gate dielectric layer (not shown) and a gate electrode located above the gate dielectric layer.

In some embodiments, the above-mentioned gate structures 126, 216 and 226 are located on the surface of the epitaxial layer 102 and may be formed in the same process to simplify the process.

According to an embodiment, after the gate structures 126, 216 and 226 are formed, an insulating layer 500 is formed above the epitaxial layer 102, and the insulating layer 500 covers the gate structures 126, 216 and 226. Next, a plurality of contact holes (not shown) are formed in the insulating layer 500, and these contact holes expose the top surfaces of the gate structures, the source regions, the drain regions and the bulk regions of each device. In some embodiments, contact holes that may expose the top surface of the trench structure 118 in the first doping region 110 and the top surface of the trench isolation 211 in the second doping region 210 is also formed in the insulating layer 500. The contact holes are then filled with conductive material to form contacts.

In some embodiments, the insulating layer 500 may be silicon oxide, or other suitable dielectric materials, or a combination of the foregoing materials. In some embodiments, the material of insulating layer 500 is different from the material of the gate dielectric layers of gate structures 126, 216, and 226. In some other embodiments, the material of insulating layer 500 may be the same as the material of the gate dielectric layers of gate structures 126, 216, and 226.

According to some embodiments, the insulating layer 500 having a plurality of contact holes may be formed through a deposition process, a photolithography patterning process and an etching process. In an example, First, an insulating layer 500 is deposited on the gate structure including a plurality of heavily doping portions using a deposition process. Then, a photolithography patterning process is performed to remove a portion of the insulating material to form a plurality of contact holes. The contact holes are filled with conductor material to form a plurality of contacts.

According to some embodiments, as shown in FIG. 2D, the formed contact 502 directly contacts the gate structure 126, and the contact 503 directly contacts the heavily doping portion 122 (such as the source region of the first device 11) and heavily doping portion 124. Since the heavily doping portion 124 with the second conductivity type (for example, p-type) is in direct contact with the body region 120, the formed contact 503 may have good ohmic contact with the body region 120 through the heavily doping portion 124. In addition, in some examples, the contact 508 directly contacts the trench structure 118, and the trench structure 118 may electrically connect the gate structure 126 or the heavily doping portion 122 functioned as the source region of the first device according to the application design.

Furthermore, according to some embodiments, as shown in FIG. 2D, in the NMOS device 21N, the formed contact 512 directly contacts the gate structure 216, and the contacts 513 and 514 directly contact the heavily doping portion 212 (the source region) and the heavily doping portion 213 (the drain region), respectively. The contact 515 directly contacts heavily doping portion 214 (the bulk region).

As shown in FIG. 2D, in the PMOS device 21P, the formed contact 522 directly contacts the gate structure 226, and the contacts 523 and 524 directly contact the heavily doping portion 222 (the drain region) and the heavily doping portion 223 (the source region), respectively. The contact 525 directly contacts heavily doping portion 224 (the bulk region).

Furthermore, in some embodiments, the contacts 518 and 528 directly contact the trench isolation 211 to avoid charge accumulation in the trench isolation 211. In some other embodiments, contacts 518 and 528 are not disposed and the trench isolation 211 is deemed to have a floating potential.

Each of the above contacts may include one or more material layers. In some examples, a barrier material (not shown) may be formed on the insulating layer 500 through a deposition process. The barrier material is conformally deposited in the contact hole. Then, a conductive material (not shown) is deposited on the barrier material layer and the conductive material fills the remaining space in the contact hole. Next, excess portions of the conductive material and barrier material above the insulating layer 500 are removed (for example, etched) to form a contact barrier layer and a contact conductive layer in the contact holes to form contacts.

In some embodiments, the material of the aforementioned contact barrier layer may include titanium (Ti), titanium nitride (TiN), tantalum (Ta), tantalum nitride (TaN), cobalt (Co), and other suitable barrier materials, or a combination of the aforementioned materials. In some embodiments, the contact barrier layer may be formed by a chemical vapor deposition (CVD) process, an atomic layer deposition (ALD) process, a physical vapor deposition (PVD) process, other suitable processes, or a combination of the foregoing processes.

In some embodiments, the aforementioned contact conductive layer may be a single-layer or multi-layer structure, and its conductive materials may include tungsten (W), aluminum (Al), copper (Cu), titanium (Ti), tantalum (Ta), titanium nitride (TiN), tantalum nitride (TaN), nickel silicide (NiSi), cobalt silicide (CoSi), other suitable metals, or a combination of the aforementioned materials. Furthermore, in some embodiments, the conductive material may be formed by a chemical vapor deposition process, an atomic layer deposition process, a physical vapor deposition process, other suitable processes, or a combination of the foregoing processes.

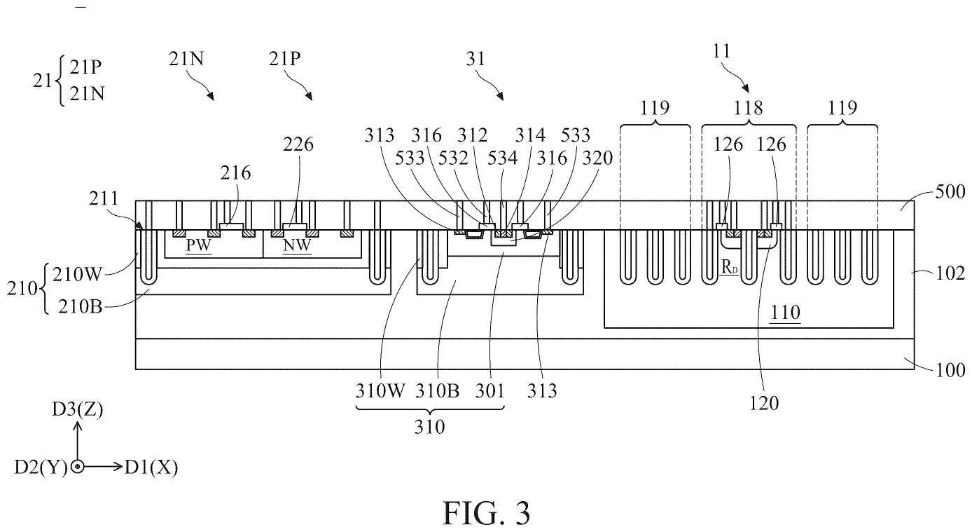

FIG. 3 is a cross-sectional view of a semiconductor structure 3 at an intermediate manufacturing stage according to some embodiments of the present disclosure. The same or similar components in FIG. 3 as in FIGS. 1 and 2A˜2D use the same or similar reference numbers, and reference may be made to the content of these components in the above embodiments, which will not be repeated in this example.

Compared with the semiconductor structure 2 of FIG. 2D, the semiconductor structure 3 of FIG. 3 further integrates a third device 31 in addition to the first device 11 and the second device 21. The components included in the first device 11 and the second device 21 are described with reference to the above exemplary embodiments. Similar to the second doping region 210 (including the buried layer 210B and the well region 210W) as shown in FIG. 2A, the third device 31 is formed in the third doping region 310. In this example, the third device 31 is, for example, a lateral diffused n-type metal oxide semiconductor (LDNMOS) device. The third doping region 310 includes, for example, a buried layer 310B, a well region 301 with different conductivity types, and a well region 310W.

In some embodiments, the well region 301 is located above the buried layer 310B and continues from the buried layer 310B. The well region 301 has the same first conductivity type as epitaxial layer 102, such as n-type. If the third device 31 is a high-voltage LDNMOS device (for example, operating at 40 V or other high voltage), the well region 301 may also be called a high-voltage n-type well region (HVNW). In some embodiments, the doping concentration of the well region 301 is greater than the doping concentration of the epitaxial layer 102. In some embodiments, the doping concentration of the well region 301 is substantially equal to the doping concentration of the first doping region 110.

In some embodiments, the well region 310W surrounds the outside of the well region 301, and the well region 310W and the buried layer 310B have the second conductivity type, such as p-type. In some embodiments, the bottom of the well region 310W further extends into the buried layer 310B, so that the third device 31 may have better electrical isolation from other components on the substrate.

Furthermore, in this example, similar to the trench isolation 211 in the second doping region 210, the trench isolation 311 is also formed in the third doping region 310. The trench isolation 311 may extend through the well region 310W into the buried layer 310B. For example, the lower portion of the trench isolation 311 is located in the buried layer 310B. In other words, the bottom surface of the trench isolation 311 is lower than the bottom surface of the well region 310W, as shown in FIG. 3.

According to the trench isolation 311 proposed in some embodiments, it may form an isolation structure with the buried layer 310B, so that the third device 31 subsequently formed in the third doping region 310 may achieve good electrical isolation with components formed outside the second doping region 310 (such as the first device 11 and the second device 21). Especially in some examples where a VDMOS device is used as the first device 11, the substrate 100 used as the drain electrode of the first device 11 is connected to a drain electrode operating voltage, which may easily cause other integrated components on the substrate 100 (such as the second device 21 of the second doping region 210 and the third device 31 of the third doping region 310) to be electrically unstable. The above problem may be solved through the isolation structure formed by the buried layer 310B and the trench isolation 311.

In some embodiments where an LDNMOS device is used as the third device 31, as shown in FIG. 3, the third device 31 includes a heavily doping portion 312 (the source region) and a heavily doping portion 313 (the drain region) and the heavily doping portion 314 (the bulk region). In this example, the heavily doping portion 312 and the heavily doping portion 313 have the same first conductivity type, such as n-type. The heavily doping portion 314 has the second conductivity type, such as p-type. Furthermore, the heavily doping portion 312 and the heavily doping portion 314 may be further formed in a body region 320 having the second conductivity type.

In this example, the third device 31 further includes a gate structure 316 located between the heavily doping portion 312 (the source region) and the heavily doping portion 313 (the drain region). The gate structure 316 includes, for example, a gate dielectric layer (not shown) and a gate electrode located above the gate dielectric layer. For details of its manufacturing method and materials, please refer to the above description of the gate structures 126, 216, and 226.

In this example, a plurality of contacts is formed in the insulating layer 500 to electrically connect the third device 31. For example, a contact 532 that directly contacts the gate structure 316, a contact 533 that directly contacts the heavily doping portion 313 (the drain region), and a contact 534 that directly contacts the heavily doping portion 312 (the source region) and the heavily doping portion 314 (the bulk region). For details of the manufacturing methods and materials of the contacts 532, 533, and 534, please refer to the above descriptions of the contacts 502, 503, 512, 513, 514, 515, 522, 523, 524, and 525.

Furthermore, similar doping regions among the first doping region 110, the second doping region 210 and the third doping region 310 may be made together in the same process to save manufacturing steps. For example, the buried layer 310B of the third doping region 310 and the buried layer 210B of the second doping region 210 may be made in the same process, and the well region 310W of the third doping region 310 may be made with the well region of 210W of the second doping region 210 in the same process. Similar components among the first device 11, the second device 21 and the third device 31 may be made together in the same process to save manufacturing steps. For example, the first device 11, the second device 21, and the third device 31 include gate structures of the same or similar configuration and are made in the same process. For example, multiple related contacts of the first device 11, the second device 21 and the third device 31 may be made in the same process. Accordingly, the semiconductor structure proposed by the embodiment, which includes integrating different types of MOS components on the same substrate, may be completed without increasing manufacturing costs.

Furthermore, according to some embodiments, the contacts formed after device integration have top surfaces with substantially the same height, for example, level with the top surface of the insulating layer 500, so that the resulting semiconductor structure has a flat top surface, which facilitates fabrication of subsequent components above the insulation layer.

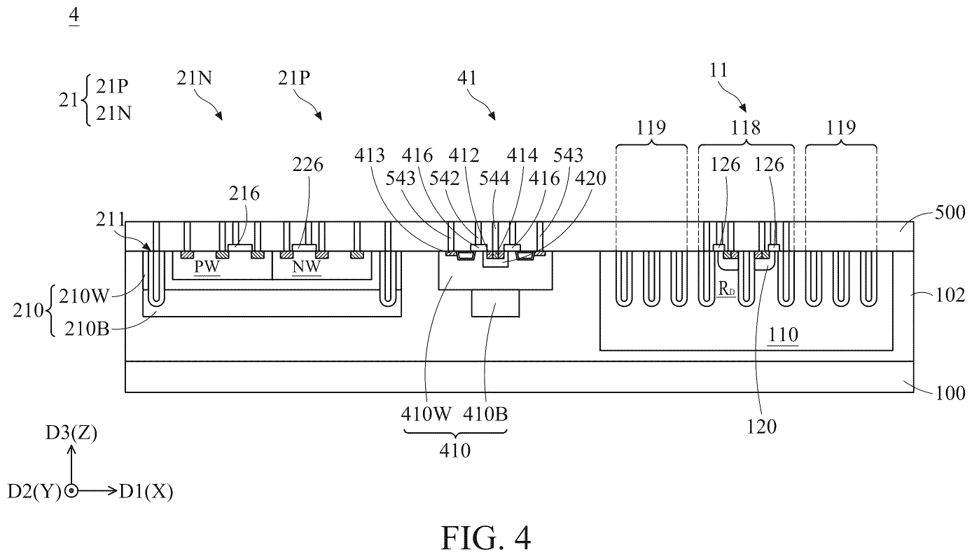

FIG. 4 is a cross-sectional view of a semiconductor structure 4 at an intermediate manufacturing stage according to some embodiments of the present disclosure. The same or similar components in FIG. 4 as those in FIGS. 1, 2A˜2D, and 3 use the same or similar reference numbers, and reference may be made to the content of these components in the above embodiments, which will not be repeated in this example.

Compared with the semiconductor structure 2 of FIG. 2D, the semiconductor structure 4 of FIG. 4 further integrates another device in addition to the first device 11 and the second device 21. For the convenience of explanation, it is referred to as the fourth device 41 here. The fourth device 41 is formed in the fourth region 410. In this example, the fourth device 41 is, for example, a lateral diffused p-type metal oxide semiconductor (LDPMOS) device. The fourth region 410 includes, for example, a buried layer 410B and a well region 410W located above the buried layer 410B. The well region 410W and the buried layer 410B have the same second conductivity type, such as p-type. If the fourth device 41 is a high-voltage LDPMOS device (for example, operating at 40V or other high voltage), the well region 410W may also be referred to as a high-voltage p-type well region (HVPW). In some embodiments, the doping concentration of the well region 410W is greater than the doping concentration of the buried layer 410B.

In some embodiments, the fourth device 41 also includes a heavily doping portion 412 (the source region), a heavily doping portion 413 (the drain region), a heavily doping portion 414 (the bulk region) and a gate structure 416. In this example, the heavily doping portion 412 and the heavily doping portion 413 have the same second conductivity type, such as p-type. The heavily doping portion 414 has the first conductivity type, such as n-type. Furthermore, the heavily doping portion 412 and the heavily doping portion 414 may be further formed in a well region 420 having the first conductivity type.

In this example, a plurality of contacts is further formed in the insulating layer 500 to electrically connect the fourth device 41. For example, a contact 542 that directly contacts the gate structure 416, a contact 543 that directly contacts the heavily doping portion 413 (the drain region), and a contact 544 that directly contacts the heavily doping portion 412 (the source region) and the heavily doping portion 414 (the bulk region).

For the configuration, materials, and manufacturing methods of each component of the fourth device 41, reference may be made to the description of the first device 11, the second device 21, and/or the third device 31 and other related components, and will not be repeated here. Furthermore, in the first device 11, the second device 21 and the fourth device 41, similar doping regions may be made together in the same process. Also, components of the same or similar configuration (for example, heavily doping portion, gate structures, contacts or the like with the same conductivity type) of each device may be made together in the same process to save manufacturing steps.

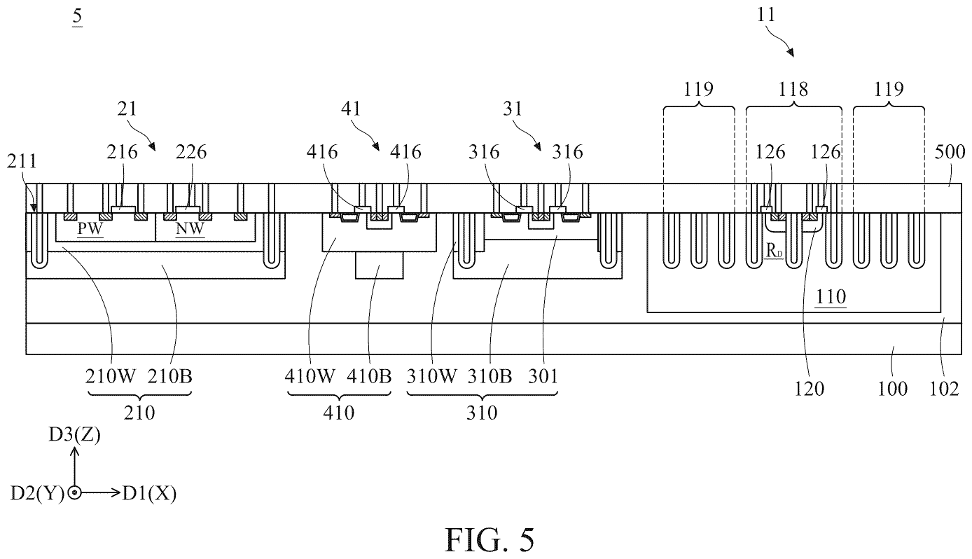

FIG. 5 is a cross-sectional view of a semiconductor structure 5 at an intermediate manufacturing stage according to some embodiments of the present disclosure. The same or similar components in FIG. 5 as those in FIGS. 1, 2A˜2D, 3, and 4 use the same or similar reference numbers, and reference may be made to the content of these components in the above embodiments, which will not be repeated in this example. The semiconductor structure 5 in FIG. 5 integrates the first device 11, the second device 21, the third device 31 and the fourth device 41. For the configuration, materials and manufacturing methods of each component of these devices, please refer to the content of these components in the above embodiments.

Based on the above, according to the semiconductor structure and the method for forming the same proposed by some embodiments of the present disclosure, a semiconductor structure including a variety of different types of MOS devices may be produced. Each MOS device may be operated in the corresponding doping region and may have good electrical performance. According to some embodiments, the semiconductor structure integrating multiple MOS devices includes vertical MOS devices and non-vertical MOS devices (such as lateral MOS devices). The substrate of the semiconductor structure includes dopants with a high doping concentration, which functions as a drain region of a vertical MOS device. According to some embodiments, the non-vertical MOS device may reduce the influence of the substrate on the electrical performance of the non-vertical MOS device through the buried layer (such as the buried layer 210B). The conductivity type of the buried layer is opposite to that of the substrate and the epitaxial layer on the substrate to avoid the undesirable vertical electric field generated by the substrate with high doping concentration corresponding to the non-vertical MOS device. In some examples, the substrate of the semiconductor structure has the first conductivity type (such as n-type) and the buried layer has the second conductivity type (such as p-type). Furthermore, in some embodiments, a region with high doping concentration (such as the first doping region 110) may be formed in the epitaxial layer at a position corresponding to the vertical MOS device. Since this region is adjacent to the substrate, the electrical performance of vertical MOS components is thus further improved. Furthermore, according to some embodiments of the present disclosure, different types of MOS devices (such as non-vertical and vertical MOS devices) may be freely selected and combined in a semiconductor structure through the doping regions. These MOS devices are electrically isolated from each other and good electrical performance may be achieved. For example, according to embodiments, BCD (including bipolar devices, CMOS devices and DMOS devices) and VDMOS devices may be integrated on the same wafer to comprehensively solve complex application design problems with high power requirements. In addition, according to the formation methods proposed in some embodiments of the present disclosure, semiconductor devices including different types of MOS devices may be manufactured through simplified processes that are compatible with existing manufacturing processes. Therefore, the manufacturing process of the embodiment is simple and does not significantly increase additional manufacturing costs.

Although the embodiments and advantages of the present disclosure have been disclosed above, it should be understood that anyone with ordinary knowledge in the art may make changes, substitutions and modification without departing from the spirit and scope of the disclosure. In addition, the protection scope of the present disclosure is not limited to the processes, machines, manufacturing, material compositions, devices, methods and steps in the specific embodiments described in the specification. Anyone with ordinary knowledge in the relevant technical field may learn from some implementations of the present disclosure. It is understood that processes, machines, manufacturing, material compositions, devices, methods and steps currently or developed in the future may be based on the disclosure of the examples as long as they may perform substantially the same functions or obtain substantially the same results in the some embodiments of the present disclosure described herein. Therefore, the protection scope of the present disclosure includes the above-mentioned processes, machines, manufacturing, material compositions, devices, methods and steps. In addition, each claimed patent scope constitutes an individual embodiment, and the protection scope of the present disclosure also includes the combination of each claimed patent scope and embodiments.

What is claimed is:

1. A semiconductor structure, comprising:
a substrate having a first conductivity type;
an epitaxial layer located on the substrate, wherein the epitaxial layer has the first conductivity type;
a first doping region extending from a top surface of the epitaxial layer into the epitaxial layer and having the first conductivity type;
a first device located in the first doping region, wherein the substrate functions as a drain electrode of the first device;
a second doping region having a second conductivity type and extending from the top surface of the epitaxial layer into the epitaxial layer, wherein the second doping region is located at a side of the first doping region, wherein a portion of the epitaxial layer extends between the first doping region and the second doping region to separate the first doping region and the second doping region; and
a second device located in the second region.

2. The semiconductor structure as claimed in claim 1, wherein a doping concentration of the first doping region is greater than a doping concentration of the epitaxial layer.

3. The semiconductor structure as claimed in claim 1, wherein a doping concentration of the substrate is greater than a doping concentration of the first doping region.

4. The semiconductor structure as claimed in claim 1, wherein a first distance is from a bottom surface of the first doping region to a top surface of the substrate, wherein a second distance is from a bottom surface of the second doping region to the top surface of the substrate, wherein the second distance is greater than the first distance.

5. The semiconductor device as claimed in claim 1, further comprising:
a trench structure located in the first doping region, wherein the trench structure extends from the top surface of the epitaxial layer in a direction of the substrate into the first doping region.

6. The semiconductor structure as claimed in claim 5, wherein a vertical distance from a bottom surface of the first doping region to a top surface of the substrate is less than a vertical distance from a bottom surface of the trench structure to the bottom surface of the first doping region.

7. The semiconductor structure as claimed in claim 5, wherein the first doping region and the second doping region are separated in a first direction, and the trench structure extends in a second direction, wherein the first direction is different from the second direction.

8. The semiconductor structure as claimed in claim 1, further comprising:
a trench isolation extending from the top surface of the epitaxial layer in a direction of the substrate into the second doping region, wherein in a top-view from above the substrate, the trench isolation surrounds a periphery of the second device.

9. The semiconductor structure as claimed in claim 1, wherein the second doping region comprises:
a buried layer having the second conductivity type; and
a well region having the second conductivity type, wherein the well region extends from the top surface of the epitaxial layer into the buried layer, wherein the second device is located in the well region,
wherein a doping concentration of the buried layer is different from a doping concentration of the well region.

10. The semiconductor structure as claimed in claim 9, wherein a doping concentration of the well region is greater than a doping concentration of the buried layer.

11. The semiconductor structure as claimed in claim 9, wherein a horizontal position of the buried layer is between a bottom surface of the first doping region and the well region.

12. The semiconductor structure as claimed in claim 9, further comprising:
a trench structure located in the first doping region, wherein the trench structure extends from the top surface of the epitaxial layer in a direction of the substrate into the first doping region,
wherein a bottom surface of the trench structure is closer to a top surface of the substrate than a bottom surface of the well region of the second doping region.

13. The semiconductor structure as claimed in claim 9, further comprising:
a trench isolation located in the second doping region, wherein the trench isolation extends from the top surface of the epitaxial layer in a direction of the substrate into the buried layer.

14. The semiconductor structure as claimed in claim 13, wherein a lower portion of the trench isolation is located in the buried layer.

15. The semiconductor structure as claimed in claim 1, wherein the first device and the second device each comprise a planar gate structure on the top surface of the epitaxial layer.

16. The semiconductor structure as claimed in claim 1, further comprising:
a body region located in the first doping region, wherein the body region extends from the top surface of the epitaxial layer into the epitaxial layer, wherein the body region has the second conductivity type;
a first heavily doping portion located in the body region and extending downward from the top surface of the epitaxial layer, wherein the first heavily doping portion has the first conductivity type, and the first heavily doping portion is a source region of the first device; and
a first gate structure located on the top surface of the epitaxial layer and corresponding to the first doping region, wherein the first gate structure spans the body region and the first heavily doping portion.

17. The semiconductor structure as claimed in claim 16, further comprising:
a second heavily doping portion and a third heavily doping portion located in the second doping region, wherein the second heavily doping portion and the third heavily doping portion extends from the top surface of the epitaxial layer into the epitaxial layer to respectively function as a source region and a drain region of the second device; and
a second gate structure located on the top surface of the epitaxial layer and corresponding to the second doping region, wherein the second gate structure is located between the second heavily doping portion and the third heavily doping portion.

18. The semiconductor structure as claimed in claim 1, further comprising:
a third device located in the second doping region or located in another region which has the second conductivity type, wherein the third device is located at a side of the second device.

19. The semiconductor structure as claimed in claim 1, further comprising:
a third doping region extending from the top surface of the epitaxial layer, wherein the third doping region has the second conductivity type, the third doping region is located between the first doping region and the second doping region, and the third doping region is separated from the first doping region and the second doping region by a portion of the epitaxial layer; and
a third device located in the third doping region.

20. The semiconductor structure as claimed in claim 1, wherein the first device is a vertical double-diffused metal oxide semiconductor (VDMOS).

21. A method for forming a semiconductor device, comprising:
providing a substrate having a first conductivity type;
forming an epitaxial layer on the substrate, wherein the epitaxial layer has the first conductivity type;
forming a first doping region in the epitaxial layer, wherein the first doping region extends from a top surface of the epitaxial layer in a direction toward the substrate, wherein the first doping region has the first conductivity type;
forming a first device in the first doping region, wherein the substrate functions as a drain electrode;
forming a second doping region in the epitaxial layer, wherein the second doping region extends from the top surface of the epitaxial layer in a direction toward the substrate, the second doping region has a second conductivity type, the second doping region is located at a side of the first doping region, and a portion of the epitaxial layer extends between the first doping region and the second doping region to separate the first doping region and the second doping region; and
forming a second device in the second doping region.

22. The method as claimed in claim 21, further comprising:
forming a trench structure in the first doping region, wherein the trench structure extends from the top surface of the epitaxial layer in a direction of the substrate into the first doping region.

23. The method as claimed in claim 22, further comprising:
forming a trench isolation in the second doping region, wherein the trench isolation extends from the top surface of the epitaxial layer in a direction of the substrate into the second doping region, wherein the trench isolation surrounds a periphery of the second device.

24. The method as claimed in claim 23, wherein the trench structure and the trench isolation are made in a same process.

25. The method as claimed in claim 21, further comprising:
forming a first gate structure on the top surface of the epitaxial layer, wherein the first gate structure corresponds to the first doping region; and
forming a second gate structure on the top surface of the epitaxial layer, wherein the second gate structure corresponds to the second doping region,
wherein the first gate structure and the second gate structure are made in a same process.

26. The method as claimed in claim 25, further comprising:
forming a body region in the first doping region, wherein the body region has the second conductivity type and extends from the top surface of the epitaxial layer into the epitaxial layer;
forming a first heavily doping portion in the body region, wherein the first heavily doping portion extends downward from the top surface, wherein the first heavily doping portion has the first conductivity type and functions as a source region of the first device; and
forming a second heavily doping portion and a third heavily doping portion in the second doping portion region, wherein the second heavily doping portion extends downward from the top surface of the epitaxial layer to respectively function as a source region and a drain region of the second device.

27. The method as claimed in claim 26, further comprising:
forming an insulating layer on the epitaxial layer, wherein the insulating layer covers the first gate structure and the second gate structure;
forming a first gate contact connected to the first gate structure, a second gate contact connected to the second gate structure, a first source contact connected to the first heavily doping portion, a second source contact connected to the second heavily doping portion, and a drain contact connected to the third heavily doping portion in the insulating layer,
wherein the first gate contact, the second gate contact, the first source contact, the second source contact and the drain contact are made in a same process.
